(19) United States
(12) Patent Application Publication
(10) Pub. No.: US 2026/0282236 A1
(43) Pub. Date: Sep. 17, 2026

(54) WIRING BOARD, ELECTRONIC DEVICE, AND ELECTRONIC MODULE

(71) Applicant: KYOCERA Corporation, Kyoto-shi, Kyoto (JP)

(72) Inventor: Yuuya MATSUMOTO, Kyoto-shi (JP)

(73) Assignee: KYOCERA Corporation, Kyoto-shi, Kyoto (JP)

(21) Appl. No.: 19/116,109

(22) PCT Filed: Sep. 5, 2023
(86) PCT No.: PCT/JP2023/032356

§ 371 Date: Mar. 27, 2025

(30) Foreign Application Priority Data
Sep. 30, 2022 (JP) 2022-158200

(51) Int. Cl. H05K 1/183; H03H 9/05; H03H 9/17; H05K 1/11

(52) U.S. Cl. CPC H05K 1/183; H03H 9/0538; H03H 9/17; H05K 1/113; H05K 2201/09036; H05K 2201/09045; H05K 2201/10075; H05K 2201/10424

(57) ABSTRACT

A wiring board includes an insulation substrate having a first surface and a second surface, first and third external electrodes located at opposing corner portions along a first diagonal line of the first surface, second and fourth external electrodes located at opposing corner portions along a second diagonal line, a first connection electrode at least partially overlapping the first external electrode and connected to the first external electrode via a first through-hole conductor extending from the first surface toward the bottom surface of a recessed portion, and a second connection electrode at least partially overlapping the third external electrode and connected to the third external electrode via a second through-hole conductor extending from the first surface toward the bottom surface of the recessed portion.

### TECHNICAL FIELD

The present disclosure relates to a wiring board for mounting an electronic component thereon, an electronic device, and an electronic module.

### BACKGROUND OF INVENTION

Various forms of package-type wiring boards that can be connected to external devices and used together with electronic circuit components have been proposed, and they can be surface-mounted on mounting boards.

Patent Document 1 discloses a wiring board including an external electrode located on a first surface of a rectangular insulation substrate and a connection electrode located on a second surface of the insulation substrate and having a rectangular electronic component mounted thereon in a plan view.

The connection electrode includes first and second connection electrodes located along one side of the electronic component. The external electrode includes first to fourth external electrodes located at four corners of the insulation substrate. Provided inside the insulation substrate are an oblique wiring that electrically connects the second and fourth external electrodes located on a diagonal line of the first surface in a plan view and includes a portion inclined with respect to the second surface, and an embedded wiring extending from the second connection electrode corresponding to the second external electrode toward the third external electrode in a plan view.

### CITATION LIST

### Patent Literature

Patent Document 1: WO 2019/146699 pamphlet

### SUMMARY

A wiring board according to an aspect of the present disclosure includes an insulation substrate having a first surface, a second surface located on an opposite side of the first surface, and a recessed portion opened on the second surface, the insulation substrate having a rectangular shape in a plan view; an external electrode located on the first surface; and a connection electrode located on a bottom surface of the recessed portion, in which the external electrode includes first and third external electrodes located at opposing corner portions along a first diagonal line of the first surface and electrically connected to the connection electrode, and second and fourth external electrodes located at opposing corner portions along a second diagonal line, the second and fourth external electrodes being connected by a connection wiring located inside the insulation substrate and having a portion inclined with respect to the first surface, the wiring board further includes a first through-hole conductor at least partially overlapping the first external electrode in a plane perspective and extending toward the bottom surface from the first surface, and a second through-hole conductor at least partially overlapping the third external electrode in a plane perspective and extending toward the bottom surface from the first surface, and the connection electrode includes a first connection electrode connected to the first external electrode via the first through-hole conductor, and a second connection electrode connected to the third external electrode via the second through-hole conductor, the first connection electrode and the second connection electrode being located at positions along the first diagonal line in a plane perspective.

An electronic device according to another aspect of the present disclosure includes the wiring board according to the aspect of the present disclosure and an electronic component connected to the wiring board.

An electronic module according to another aspect of the present disclosure includes the electronic device according to the aspect of the present disclosure and a module board connected to the electronic device.

### BRIEF DESCRIPTION OF THE DRAWINGS

FIG. 1 is an overall perspective view of an electronic device according to a first embodiment when viewed in a state in which a lid is removed.

FIG. 2 is a perspective view of a wiring board of the electronic device when viewed from a lower surface side.

FIG. 3 is a plan view of the wiring board provided in the electronic device.

FIG. 4 is a perspective view of a configuration of the lower surface of the wiring board when viewed from above.

FIG. 5 is a perspective view of the configurations of the upper and lower surfaces of the wiring board when superimposed.

FIG. 6 is a cross-sectional view of the wiring board taken along an arrow line VI-VI illustrated in FIG. 3.

FIG. 7 is a cross-sectional view of the wiring board taken along an arrow line VII-VII illustrated in FIGS. 3 and 4.

FIG. 8 is a cross-sectional view of the wiring board taken along an arrow line VIII-VIII illustrated in FIG. 4.

FIG. 9 is a plan view of a wiring board according to a second embodiment.

FIG. 10 is a cross-sectional view of the wiring board taken along an arrow line X-X illustrated in FIG. 9.

FIG. 11 is a plan view of a wiring board according to a third embodiment.

FIG. 12 is a cross-sectional view of the wiring board taken along an arrow line XII-XII illustrated in FIG. 11.

FIG. 13 is a cross-sectional view of a wiring board according to a fourth embodiment.

FIG. 14 is a perspective view of the configurations of upper and lower surfaces of the wiring board according to a fifth embodiment when superimposed.

FIG. 15 is a perspective view of the configurations of upper and lower surfaces of the wiring board according to a sixth embodiment when superimposed.

FIG. 16 is a plan view of a wiring board according to a seventh embodiment.

FIG. 17 is a plan view of a variation of the wiring board.

FIG. 18 is a plan view of another variation of the wiring board.

FIG. 19 is a plan view of still another variation of the wiring board.

### DESCRIPTION OF EMBODIMENTS

### First Embodiment

Embodiments of the present disclosure will be described below with reference to the accompanying drawings. It is desired to provide a wiring board having a configuration capable of ensuring insulation between internal wirings even when the height is further reduced. According to an aspect of the present disclosure, insulation between the internal wirings can be ensured even when the height is further reduced.

The distinction between top and bottom in the following description is for convenience only and does not limit the actual top and bottom of the wiring board and the electronic device when they are used. In this specification, an upper surface is defined as a surface on which an electronic component 150 is mounted on an insulation substrate 110 or a wiring board 100. In the drawings, the positive Z-axis direction is the upward direction. The X-axis direction is the longitudinal direction of the insulation substrate 110 or the wiring board 100, and the Y-axis is the axis that orthogonally intersects the X-axis and the Z-axis.

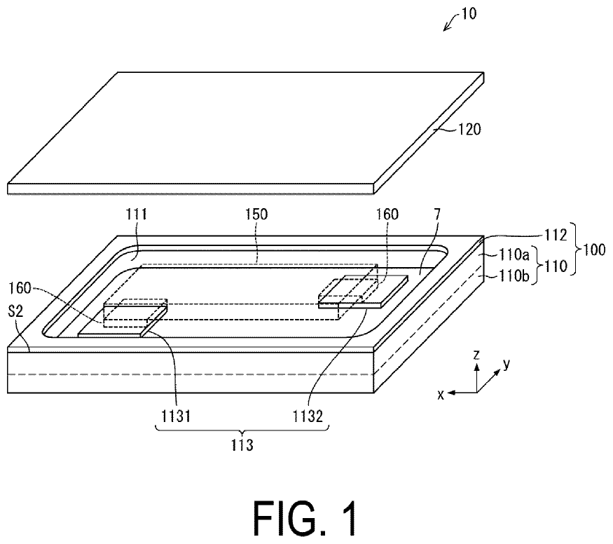

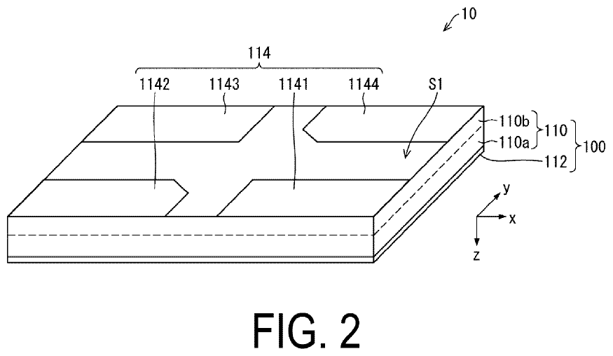

FIG. 1 is an overall perspective view of an electronic device 10 according to the present embodiment when viewed in a state in which a lid 120 is removed. FIG. 1 illustrates an upper surface of the side to which the lid 120 is bonded. FIG. 2 is a perspective view of the wiring board 100 of the electronic device 10 when viewed from a lower surface opposite to the side to which the lid 120 is bonded.

The electronic device 10 includes the wiring board 100, the electronic component 150, and the lid 120. The wiring board 100 includes the insulation substrate 110, electrodes (connection electrode 113 and external electrode 114), and wiring.

The insulation substrate 110 has a first surface S1 opposite to the side to which the lid 120 is bonded, a second surface S2 located on the opposite side of the first surface S1, and a recessed portion 111 which is a recessed area opened on the second surface S2. The insulation substrate 110 includes a base portion 110b having a flat plate shape and a frame portion 110a located on an upper surface of the base portion 110b.

The electronic component 150 is located inside the recessed portion 111. The frame portion 110a defines an open surface of the recessed portion 111, a bottom surface 7 (mounting surface for the electronic component 150) opposite to the open surface, and side surfaces of the recessed portion 111. Each of the side surfaces of the recessed portion 111 is parallel to the Z-direction. In this specification, the description “parallel” only means to be not intersecting a reference plane or a reference line at a visible level, and does not need to be strictly parallel.

A frame-shaped metallized layer 112 is located on the upper surface of the frame portion 110a, that is, on the bonding surface between the frame portion 110a and the lid 120. The frame-shaped metallized layer 112 is bonded to the lid 120 using a sealing material such as a gold-tin alloy (AuSn) or silver solder. Although not particularly limited, the size of the wiring board 100 is about 0.8 mm to 10.0 mm on one side in the XY plane and about 0.1 mm to 2.0 mm thick in the Z-direction. The wiring board 100 according to the present embodiment is particularly useful when it is difficult to ensure insulation, that is, when the thickness of the wiring board 100 is 0.2 mm or less and the thickness of the base portion 110 b is 0.1 mm or less.

A first connection electrode 1131 and a second connection electrode 1132 are located on the bottom surface 7 of the recessed portion 111. The first connection electrode 1131 and the second connection electrode 1132 may be collectively referred to as a connection electrode 113. By attaching the electronic component 150 to the connection electrode 113, that is, by connecting the electronic component 150 to the wiring board 100, the electronic device 10 including the wiring board 100 and the electronic component 150 is formed.

The electronic component 150 and the connection electrode 113 are connected to each other via a bonding material 160 as an electrically conductive adhesive. The bonding material 160 may be, for example, a resin to which conductive particles of silver or the like are added. When the bonding material 160 is a thermosetting material, the bonding material 160 is applied to the connection electrode 113 in advance, and the electronic component 150 is positioned and arranged with respect to the connection electrode 113 (bonding material 160) and heated, whereby the electronic component 150 is connected to the connection electrode 113 via the bonding material 160. The connection electrode 113 may have a protruding shape with respect to the bottom surface 7 of the recessed portion 111. This allows the electronic component 150 to be fixed separated from the bottom surface 7 in the recessed portion 111. In a case in which the electronic component 150 generates vibrations or the like during operation, the thickness of the connection electrode 113 and the bonding material 160 may be determined so as not to allow the electronic component 150 to come into contact with the bottom surface and the lid 120 in the recessed portion 111 during vibrations.

The connection electrode 113 may be embedded in the bottom surface 7 of the recessed portion 111, with the upper surface of the connection electrode 113 positioned on the same plane as the bottom surface 7. This makes it possible to further reduce the height of the wiring board 100. In this case, the bonding material is located on the upper surface of the connection electrode 113, and the electronic component 150 is located on the bonding material. As a result, the electronic component 150 is fixed separated from the bottom surface 7 in the recessed portion 111.

A first external electrode 1141, a second external electrode 1142, a third external electrode 1143, and a fourth external electrode 1144 are located at four corners of the first surface S1 on the opposite side of the recessed portion 111 of the base portion 110b. The first external electrode 1141, the second external electrode 1142, the third external electrode 1143, and the fourth external electrode 1144 may be collectively referred to as an external electrode 114. The external electrode 114 is an external electrode bonded to a module board 200. In the external electrode 114, the first external electrode 1141 and the third external electrode 1143 are electrodes to which a potential corresponding to a supply voltage to the electronic component 150 is applied, and the second external electrode 1142 and the fourth external electrode 1144 are grounded electrodes.

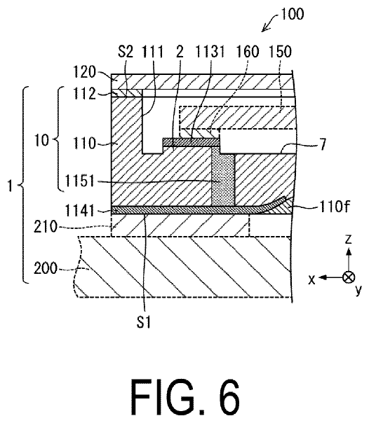

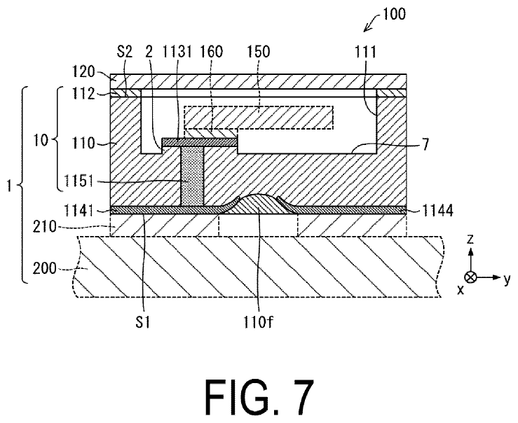

An electronic module 1 includes the electronic device 10 together with the module board 200 to which the external electrode 114 is bonded using a solder 210 (see FIGS. 6 and 7). As the electronic component 150, a component such as a piezoelectric oscillating element used for an oscillator, a resonator, or the like, or a crystal resonator may be used. A plurality of electronic components 150 may be located in one recessed portion 111, as necessary.

The insulation substrate 110 is made of a ceramic material such as an aluminum oxide sintered body, an aluminum nitride sintered body, a mullite sintered body, a glass ceramic sintered body, or the like. Here, it is assumed that the insulation substrate 110 is an aluminum oxide sintered body (alumina sintered body). The frame portion 110a and the base portion 110b of the insulation substrate 110 are formed integrally.

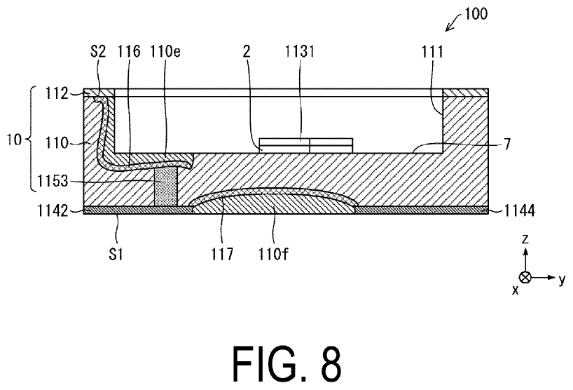

The lid 120 is made of a conductor metal and is bonded to the frame-shaped metallized layer 112 to hermetically seal the recessed portion 111. For sealing, an electrically conductive sealing member (sealing material) such as AuSn or silver solder is used. The lid 120 may be grounded. Grounding the lid 120 can reduce the propagation of external noise into the recessed portion 111. The lid 120 is connected to the frame-shaped metallized layer 112 via the electrically conductive sealing member. As illustrated in FIG. 8, the frame-shaped metallized layer 112 is connected to the second external electrode 1142 of the wiring board 100 via an in-frame wiring 116 and a via conductor 1153. The in-frame wiring 116 and the via conductor 1153 will be described later. Grounding the second external electrode 1142 makes the lid 120 be in the grounded state.

The frame-shaped metallized layer 112 is made of a conductor metal and formed by printing on the bonding surface of the frame portion 110a. The frame-shaped metallized layer 112, an exposed surface of the connection electrode 113, an exposed surface of the external electrode 114, and the like may be coated with a plating layer made of nickel and/or gold. For example, nickel plating may be applied to the exposed surface at a thickness of 1 μm to 20 μm, and a gold plating layer may be applied over this nickel plating layer at a thickness of 0.1 μm to 3.0 μm. This decreases the likelihood of the surface oxidation corrosion and also provides an easier and stronger connection between the frame-shaped metallized layer 112 located on the upper surface of the insulation substrate 110 being an insulator, and the lid 120 being a metal conductor.

The electric wiring in the wiring board 100 is described.

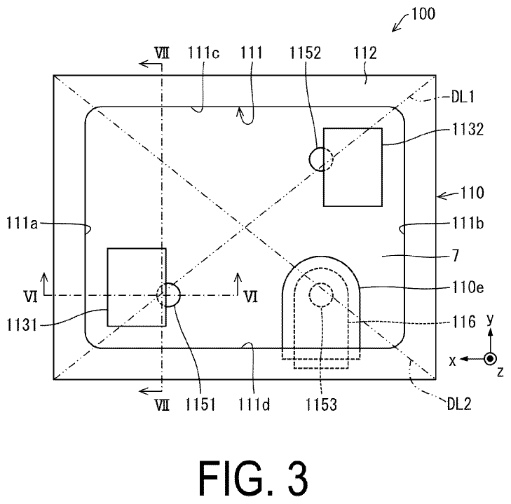

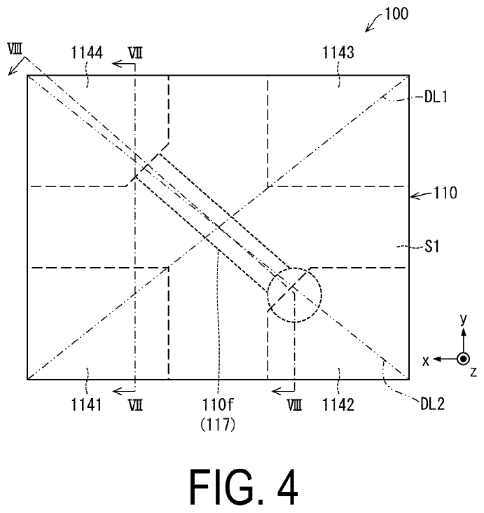

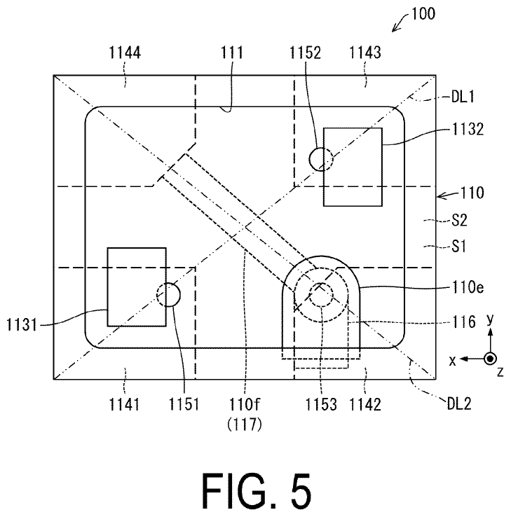

FIG. 3 is a plan view of the wiring board 100. FIG. 4 is a perspective view of the configuration of the first surface S1 of the wiring board 100 when viewed from the second surface S2 side. FIG. 5 is a perspective view of the configurations of the second surface S2 and the first surface S1 of the wiring board 100 when superimposed. FIG. 6 is a cross-sectional view of the wiring board 100 taken along an arrow line VI-VI illustrated in FIG. 3. FIG. 7 is a cross-sectional view of the wiring board 100 taken along an arrow line VII-VII illustrated in FIGS. 3 and 4. FIG. 8 is a cross-sectional view of the wiring board 100 taken along an arrow line VIII-VIII illustrated in FIG. 4. FIGS. 6 and 7 illustrate the entire electronic module 1 including the electronic component 150 connected to the connection electrode 113, the lid 120 bonded to the frame-shaped metallized layer 112, and the module board 200 connected to the external electrode 114 via the solder 210 (as the electronic module 1, the electronic device 10 is attached to the module board 200).

As illustrated in FIG. 6, the first connection electrode 1131 located on the bottom surface 7 of the recessed portion 111 is connected to the first external electrode 1141 located immediately below through a first through-hole conductor 1151 which vertically penetrates the insulation substrate 110 (base portion 110b). The second connection electrode 1132 is connected to the third external electrode 1143 located immediately below through a second through-hole conductor 1152 which vertically penetrates the insulation substrate 110 (base portion 110b).

A floating island portion 2 having a protruding shape may be located on the bottom surface of the recessed portion 111. The first connection electrode 1131 may be located on the floating island portion 2. The floating island portion 2 may be made of the same material as that of the insulation substrate 110, and may be formed integrally with the insulation substrate 110. A thickness (length in the Z-direction) of the floating island portion 2 can be adjusted as appropriate according to the characteristics, shape, and the like of the electronic component 150 to be mounted.

As illustrated in FIG. 8, the frame-shaped metallized layer 112 is connected to the second external electrode 1142 through the in-frame wiring 116 located inside the frame portion 110a and the base portion 110b and through the via conductor 1153. The second external electrode 1142 and the fourth external electrode 1144 are located on a second diagonal line DL2 of the wiring board 100, and are connected to each other by a connection wiring 117 (wiring provided inside the insulation substrate 110) located inside the base portion 110b. The connection wiring 117 is a wiring required for electrical conduction when the exposed surfaces of the second external electrode 1142 and the fourth external electrode 1144 are coated with a plating layer. On the other hand, the first external electrode 1141 and the third external electrode 1143, which are electrically connected to the electronic component 150, are also located on a first diagonal line DL1 of the wiring board 100.

By disposing the electrode for connection and the electrode for grounding, each on the first diagonal line DL1 and the second diagonal line DL2, even when the electronic device 10 is erroneously mounted on the module board 200 in a posture rotated by 180 degrees, the likelihood of malfunctions of the module board 200 with respect to the polarity of the electronic device 10 can be decreased.

As illustrated in FIGS. 6 and 7, the first connection electrode 1131 is connected to the first external electrode 1141 via the first through-hole conductor 1151. On the first surface S1 of the insulation substrate 110 (base portion 110b), a coating layer 110f made of the same material as that of the insulation substrate 110, that is, an aluminum oxide-based ceramic paste, is provided. The coating layer 110f allows the end portions of the first and fourth external electrodes 1141 and 1144 to enter the inside of the insulation substrate 110.

FIG. 8 is a cross-sectional view of the wiring board 100 taken along the cross-sectional line VIII-VIII, including the second external electrode 1142, the fourth external electrode 1144, and the connection wiring 117. The in-frame wiring 116 is in contact, at its first end portion, with the side opposite to the bonding surface of the frame-shaped metallized layer 112 and the lid 120, and is coated with a coating layer 110e provided to face the recessed portion 111 so as not to be exposed to the outside. The in-frame wiring 116 is in contact with the upper end of the via conductor 1153 in the vicinity of a second end portion located on the opposite side of the first end portion. The lower end of the via conductor 1153 is in contact with the second external electrode 1142. The coating layer 110e and the coating layer 110f may be made of the same material.

Two ends of the connection wiring 117 connecting the second external electrode 1142 and the fourth external electrode 1144 are in contact with the second external electrode 1142 and the fourth external electrode 1144, respectively, to electrically connect the second external electrode 1142 and the fourth external electrode 1144. The portions of the connection wiring 117 other than the two ends enter the inside of the insulation substrate 110 by the coating layer 110f described above.

The connection wiring 117 includes a portion having an extending direction thereof (that is, a direction connecting the second and fourth external electrodes 1142 and 1144) inclined with respect to the first surface S1 of the insulation substrate 110. That is, the distance from the lower surface of the insulation substrate 110 to the connection wiring 117 (the thickness of the coating layer 110f) changes along the extending direction of the connection wiring 117. The thickness of the coating layer 110f increases toward the center. This allows the connection wiring 117 to enter the inside of the insulation substrate 110 from both ends at an angle from the lower surface of the insulation substrate 110. The inclination angle of the connection wiring 117 with respect to the lower surface of the insulation substrate 110 and the length of the inclined portion may be appropriately determined according to the length of the wiring and/or the positional relationship with other wirings. The inclination angle need not be constant (that is, the connection wiring 117 is linear in a cross-sectional view), and here, the connection wiring 117 has a curved shape in a cross-sectional view.

As described above, the wiring board 100 includes the insulation substrate 110 having a rectangular shape in a plan view and including the first surface S1, the second surface S2 located on the opposite side of the first surface S1, and the recessed portion 111 opened on the second surface S2. The wiring board 100 includes the external electrode 114 located on the first surface S1 and the connection electrodes 113 located on the bottom surface of the recessed portion 111.

The external electrode 114 includes the first and third external electrodes 1141 and 1143 located at opposing corner portions of the first surface S1 along the first diagonal line DL1 and electrically connected to the connection electrode 113. The external electrode 114 includes the second and fourth external electrodes 1142 and 1144 located at opposing corner portions along the second diagonal line DL2 of the first surface S1.

The second and fourth external electrodes 1142 and 1144 are located inside the insulation substrate 110 and are connected to each other by the connection wiring 117 including the inclined portion with respect to the first surface S1.

The wiring board 100 further includes the first through-hole conductor 1151 at least partially overlapping the first external electrode 1141 in a plane perspective and extending from the first surface S1 toward the bottom surface 7. The wiring board 100 further includes the second through-hole conductor 1152 at least partially overlapping the third external electrode 1143 in a plane perspective and extending from the first surface S1 toward the bottom surface 7.

The connection electrode 113 includes the first connection electrode 1131 connected to the first external electrode 1141 via the first through-hole conductor 1151 and the second connection electrode 1132 connected to the third external electrode 1143 via the second through-hole conductor 1152.

The first connection electrode 1131 and the second connection electrode 1132 are located at positions along the first diagonal line DL1 in the plane perspective.

According to the above configuration, in a plane perspective, the first and third external electrodes 1141 and 1143 are located at the opposing corner portions along the first diagonal line DL1 of the first surface S1. The second and fourth external electrodes 1142 and 1144 are located at the opposing corner portions along the second diagonal line DL2 of the first surface S1. The second and fourth external electrodes 1142 and 1144 are located inside the insulation substrate 110, and are connected to each other by the connection wiring 117 including the portion inclined with respect to the first surface S1. The first connection electrode 1131 and the second connection electrode 1132 are located at positions along the first diagonal line DL1 in a plane perspective. Accordingly, the wiring connecting the first connection electrode 1131 and the first external electrode 1141 and the wiring connecting the second connection electrode 1132 and the third external electrode 1143 do not overlap the connection wiring 117 in a plane perspective. As a result, the height of the wiring board 100 can be reduced while ensuring insulation between the wiring for connecting the connection electrode 113 and the external electrode 114 and the connection wiring 117 for grounding.

Since the first connection electrode 1131 and the second connection electrode 1132 for connecting the electronic component 150 are located along the first diagonal line DL1, the posture of the electronic component 150 is easily stabilized when the electronic component 150 is mounted.

As illustrated in FIG. 3, the recessed portion 111 has four inner walls 111a, 111b, 111c, and 111d. The first through-hole conductor 1151 may be located inside the first external electrode 1141 and shifted from the center of the first connection electrode 1131 in a direction opposite to the inner wall 111a and/or the inner wall 111d located near the first connection electrode 1131 among the four inner walls in a plane perspective. The second through-hole conductor 1152 may be located inside the third external electrode 1143 and shifted from the center of the second connection electrode 1132 in a direction opposite to the inner wall 111b and/or the inner wall 111c located near the second connection electrode 1132 among the four inner walls in a plane perspective.

In this case, a portion of the first through-hole conductor 1151 is connected to the first connection electrode 1131. A portion of the first through-hole conductor 1151 is exposed on the side surface of the floating island portion 2 and the bottom surface 7 of the recessed portion 111.

According to the above configuration, since the first through-hole conductor 1151 is located away from the side wall of the recessed portion 111 which is subject to the thermal stress when the wiring board 100 is sealed by the lid 120, the likelihood of generation of cracks starting from the first through-hole conductor 1151 due to the thermal stress can be decreased.

The first through hole conductor 1151 may be shifted at least from the center of the first connection electrode 1131 in a direction opposite to the inner wall 111a. When the wiring board 100 has a rectangular shape which is longer in the X-direction than the Y-direction when viewed in a plan view, as illustrated in FIG. 3 and the like, the thermal stress increases in the longitudinal direction (X-direction). Therefore, shifting the first through hole conductor 1151 in the direction opposite to the inner wall 111a from the center of the first connection electrode 1131 along the X-direction is effective in decreasing the likelihood of generation of the cracks mentioned above.

At least a portion of the first through-hole conductor 1151 may be located outside the first connection electrode 1131 in a plane perspective.

According to the above configuration, the likelihood of generation of the cracks starting from the first through-hole conductor 1151 due to the thermal stress when the wiring board 100 is sealed by the lid 120 can further be decreased.

The floating island portion 2 having a protruding shape may be located on the bottom surface of the recessed portion 111, and the first connection electrode 1131 may be located on the floating island portion 2.

According to the above configuration, since the first connection electrode 1131 is located on the floating island portion 2 having the protruding shape on the bottom surface of the recessed portion 111, the shape of the first connection electrode 1131 can be maintained more easily when forming the recessed portion 111 of the insulation substrate 110.

An example of a manufacturing method for the wiring board 100 will be described.

First, through holes are formed in a ceramic green sheet which becomes the insulation substrate 110, and the conductor is injected into the through holes to form the first through-hole conductor 1151, the second through-hole conductor 1152, and the via conductor 1153.

A metalization paste is applied, using a mask, to the position of the connection electrode 113 and an appropriate position range for the formation of the in-frame wiring 116 on the upper surface of the ceramic green sheet. A ceramic paste made of the same material as that of the ceramic green sheet is applied using a mask to an appropriate position range covering the portion of the metalization paste corresponding to the in-frame wiring 116. The application of the metalization paste and the application of the ceramic paste are carried out by screen printing, for example.

Subsequently, the metalization paste is applied to individual positions of the external electrodes 114 using a mask on the lower surface side of the ceramic green sheet. The second and fourth external electrodes 1142 and 1144 are connected to each other via the metalization paste applied to the position of the connection wiring 117 in a bottom view. The ceramic paste is further applied using a mask to a region from the gap portion between the external electrodes 114 (including the portion to which the metalization paste is applied) to the vicinity of the inner boundary of the external electrodes 114. At this time, the amount of the ceramic paste applied may be increased or decreased, or made non-uniform, depending on the inclination angle of the connection wiring 117 and the like.

The ceramic green sheet with the metalization paste and the ceramic paste applied to both sides thereof is placed on a flat plate and pressed from the upper side using a pressurizing jig having irregularities of the shape corresponding to the recessed portion 111, the frame portion 110a, the floating island portion 2, and the connection electrode 113. Accordingly, the recessed portion 111 is formed, and the metalization paste that becomes the connection electrode 113 is pushed down in the direction of the bottom surface 7 of the recessed portion 111 to form the floating island portion 2 and the connection electrode 113 of the bottom surface 7. A portion of the metalization paste extending substantially parallel to the bottom surface 7 of the recessed portion 111 of the in-frame wiring 116 is trapped and embedded between the coating layer 110e and the ceramic green sheet. The upper end of the via conductor 1153 is pushed downward by the metalization paste, which becomes the in-frame wiring 116, and the ceramic paste, and thereby brought to have the shape not penetrating to the bottom surface of the recessed portion 111 from the lower surface of the insulation substrate 110.

On the other hand, along with the formation of the recessed portion 111 by the protruding portion of the pressurizing jig, the ceramic green sheet, the metalization paste, and the ceramic paste deform in the area outside the recessed portion 111 and are applied to fill the recessed portion of the pressurizing jig. This allows the metalization paste that becomes the in-frame wiring 116 trapped between the coating layer 110e and the ceramic green sheet to be embedded in the frame portion 110a.

On the lower surface side of the ceramic green sheet, the metalization paste and the ceramic paste are formed in a planar shape to form four external electrodes 114. The inner end portions of the external electrode 114 are pressed into the insulation substrate 110 by the ceramic paste. The metalization paste connecting the second and fourth external electrodes 1142 and 1144 is pushed into the inside of the insulation substrate 110 by the ceramic paste to form the connection wiring 117.

Thus, the coating layers 110f and 110e are formed integrally with the ceramic green sheet. The wiring board 100, in which the trapped metalization paste is turned out to be the in-frame wiring 116 and the connection wiring 117 which are not exposed except at the frame-shaped metallized layer 112, the connection electrode 113, and the bonding surface with the external electrode 114, is obtained by firing. Subsequently, plating, firing, mounting of the electronic components 150, and bonding of the lid 120 are carried out, as necessary.

When manufacturing the wiring board 100 using the above method, the conductor material that becomes the first through-hole conductor 1151 may flow to the wall surface side of the recessed portion 111 in forming the recessed portion 111. By designing the first through-hole conductor 1151 to be located after completion away from the side wall of the recessed portion 111, the likelihood of deviation of the conductor material of the first through-hole conductor 1151 from a connectible range with the first connection electrode 1131 can be decreased.

### Second Embodiment

Another embodiment of the present disclosure will be described below. For convenience of description, members having the same functions as those of the members described in the above-described embodiment are denoted by the same reference signs, and description thereof is not repeated.

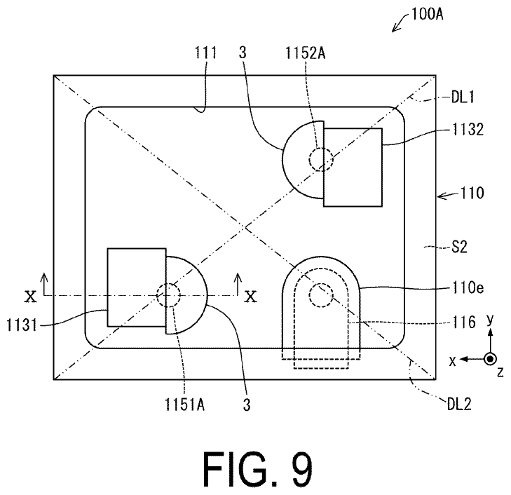

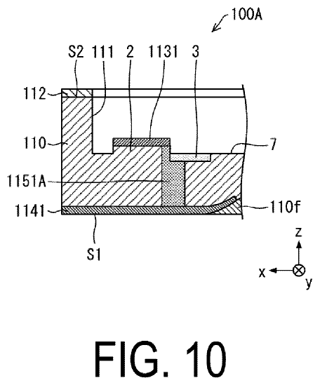

FIG. 9 is a plan view illustrating an example of a wiring board 100A according to a second embodiment. FIG. 10 is a cross-sectional view of the wiring board taken along an arrow line X-X illustrated in FIG. 9.

The wiring board 100A includes a first through-hole conductor 1151A and a second through-hole conductor 1152A.

A portion of the end surface of the first through-hole conductor 1151A on the bottom surface 7 side may be connected to the first connection electrode 1131, and an insulating coating portion 3 may be located between the remaining portion of the end surface of the first through-hole conductor 1151A and the bottom surface 7 of the recessed portion 111. For example, in a plane perspective, the end surface (upper end surface) of the first through-hole conductor 1151A overlapping the first connection electrode 1131 is connected to the lower surface of the first connection electrode 1131. On the other hand, the end surface (upper end surface) of the first through-hole conductor 1151A not overlapping the first connection electrode 1131 is in contact with the lower surface of the coating portion 3 located between this end surface and the bottom surface 7 of the recessed portion 111.

A portion of the end surface (upper end surface) of the second through-hole conductor 1152A on the bottom surface 7 side may be connected to the second connection electrode 1132, and the insulating coating portion 3 may be located between the remaining portion of the end surface of the second through-hole conductor 1152A and the bottom surface 7 of the recessed portion 111.

According to this configuration, the first and second through-hole conductors 1151A and 1152A are coated with the coating portion 3 and are not exposed on the bottom surface 7 of the recessed portion 111. Therefore, no plating is applied to the exposed surfaces of the first and second through-hole conductors 1151A and 1152A on the bottom surface 7 of the recessed portion 111. This decreases the likelihood of protrusion of the first and second through-hole conductors 1151A and 1152A from the bottom surface 7 of the recessed portion 111. As a result, the likelihood of contacting the first and second through-hole conductors 1151A and 1152A with the electronic components 150 is decreased.

### Third Embodiment

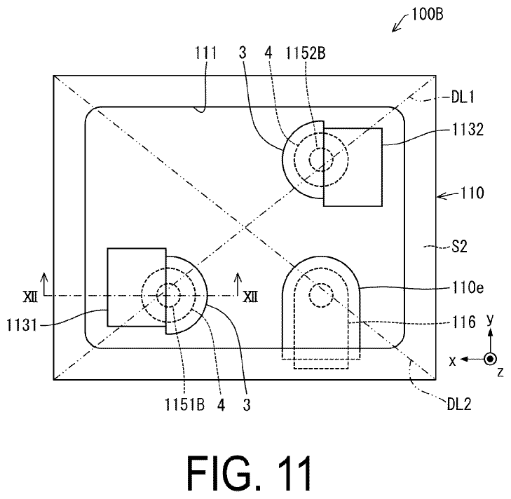

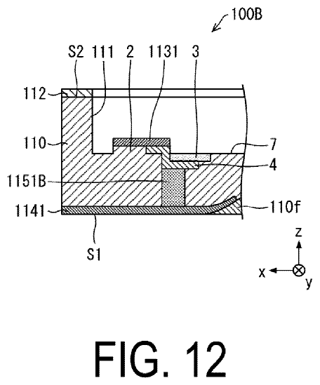

FIG. 11 is a plan view of a wiring board 100B according to a third embodiment. FIG. 12 is a cross-sectional view of the wiring board 100B taken along an arrow line XII-XII illustrated in FIG. 11.

The wiring board 100B includes a first through-hole conductor 1151B and a second through-hole conductor 1152B.

The wiring board 100B may include an internal wiring 4 being connected to an end surface on the bottom surface 7 side of the first through-hole conductor 1151B, at least a portion of the internal wiring 4 extending along a plane substantially parallel to the first surface S1, and the internal wiring 4 being provided with the first through-hole conductor 1151B located inside the internal wiring 4 in a plane perspective. The wiring board 100B may include the coating portion 3 located between the internal wiring 4 and the bottom surface 7 of the recessed portion 111 and adjacent to the first connection electrode 1131 in a plane perspective. The internal wiring 4 is a wiring that connects the first through-hole conductor 1151B and the first connection electrode 1131. In a plane perspective, the internal wiring 4 at least partially overlaps the first connection electrode 1131. In the example illustrated in FIG. 11, in a plane perspective, a portion of the first through-hole conductor 1151B overlaps the first connection electrode 1131, but the first through-hole conductor 1151B may not necessarily overlap the first connection electrode 1131.

According to this configuration, the reliability of connection between the first connection electrode 1131 and the first through-hole conductor 1151B can be improved by connecting the internal wiring 4 to the end portion of the first through-hole conductor 1151B. Since the first through-hole conductor 1151B is coated with the coating portion 3 and is not exposed on the bottom surface 7 of the recessed portion 111, no plating is applied to the exposed surface of the first through-hole conductor 1151B on the bottom surface 7 of the recessed portion 111. This decreases the likelihood of protrusion of the first through-hole conductor 1151B from the bottom surface 7 of the recessed portion 111.

The wiring board 100B may include the internal wiring 4 being connected to the end surface on the bottom surface 7 side of the second through-hole conductor 1152B, at least a portion of the internal wiring 4 extending along a plane substantially parallel to the first surface S1, and the internal wiring 4 being provided with the second through-hole conductor 1152B located inside the internal wiring 4 in a plane perspective. The wiring board 100B may include the coating portion 3 located between the internal wiring 4 and the bottom surface 7 of the recessed portion 111 and adjacent to the first connection electrode 1131 in a plane perspective.

### Fourth Embodiment

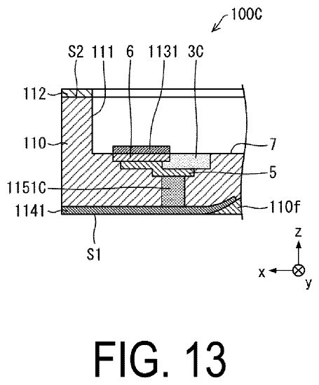

FIG. 13 is a cross-sectional view illustrating a wiring board 100C according to a fourth embodiment.

The wiring board 100C includes a first through-hole conductor 1151C.

The wiring board 100C may include a first internal wiring 5 connected to the end surface on the bottom surface 7 side of the recessed portion 111 of the first through-hole conductor 1151C, at least a portion of the first internal wiring 5 extending along a plane substantially parallel to the first surface S1, and the first through-hole conductor 1151C being located in the first internal wiring 5 in a plane perspective. The wiring board 100C may include a coating portion 3C located between the first internal wiring 5 and the bottom surface 7 of the recessed portion 111 and provided with the first through-hole conductor 1151C located inside the coating portion 3C in a plane perspective, and a second internal wiring 6 connecting the first internal wiring 5 and the first connection electrode 1131. In the wiring board 100C, at least a portion of the coating portion 3C is located below the first connection electrodes 1131. In a plane perspective of the wiring board 100C, the first through-hole conductor 1151C is located inside the coating portion 3C. The first internal wiring 5 is a wiring that connects the second internal wiring 6 and the first through-hole conductor 1151C. The shape of the second internal wiring 6 in a plan view may be substantially the same as the shape of the first connection electrode 1131.

According to this configuration, since the entire end surface of the first through-hole conductor 1151C is coated with the coating portion 3C, the likelihood of protrusion of the first through-hole conductor 1151C from the bottom surface 7 of the recessed portion 111 is further decreased.

### Fifth Embodiment

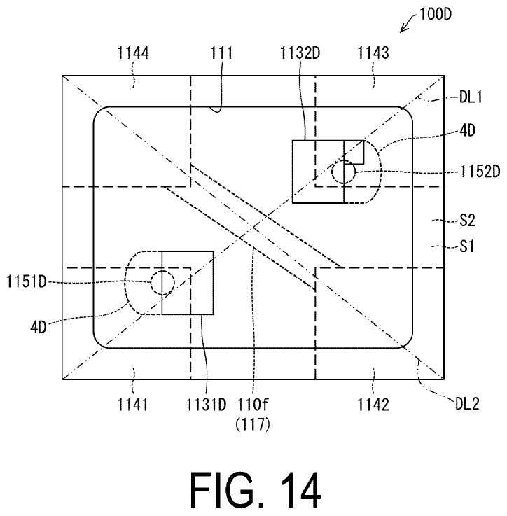

FIG. 14 is a perspective view of the configurations of an upper surface and a lower surface of a wiring board 100D according to a fifth embodiment when superimposed.

The wiring board 100D includes a first connection electrode 1131D, a second connection electrode 1132D, a first through-hole conductor 1151D, a second through-hole conductor 1152D, and an internal wiring 4D.

The first connection electrode 1131D and the second connection electrode 1132D may be located at positions of point symmetry with respect to the center of the second surface S2.

According to this configuration, the degree of freedom in mounting the electronic component 150 on the wiring board 100D is improved by moving the first connection electrode 1131D and the second connection electrode 1132D, which are located at the positions of point symmetry, according to the shape/size of the electronic component 150. Since the first connection electrodes 1131D and the second connection electrodes 1132D are located at the positions of point symmetry, the electronic component 150 can be stably mounted on the first connection electrode 1131D and the second connection electrode 1132D when the electronic component 150 also has a point symmetry shape.

The connection wiring 117 may linearly extend from the second external electrode 1142 to the fourth external electrode 1144 in a plan view. This makes the configuration of the connection wiring 117 simple and compact.

The shape of the first connection electrode 1131D and the shape of the second connection electrode 1132D may be different from each other in a plan view.

When the first connection electrode 1131D and the second connection electrode 1132D have the identical shape and are located at positions of point symmetry, it is difficult to determine the orientation of the wiring board 100D. The first connection electrode 1131D and the second connection electrode 1132D may be formed to have different shapes in a plan view. This makes it possible to use either the first connection electrode 1131D or the second connection electrode 1132D as an alignment mark, making it easier to determine the orientation of the wiring board 100D.

Even when the first connection electrode 1131D and the second connection electrode 1132D have the identical shape, a portion of the internal wiring 4D connected to the second connection electrode 1132D may be exposed on the bottom surface 7 of the recessed portion 111 and partially plated similarly to the second connection electrode 1132D, as illustrated in FIG. 14. The internal wiring 4D is connected to the second connection electrode 1132D inside the insulation substrate 110, and may be in contact with each other in a plan view, or may be separated from each other across a ceramic coating interposed therebetween. The internal wiring 4D connected to the first connection electrode 1131D is not exposed on the bottom surface 7 of the recessed portion 111. The internal wiring 4D and the first connection electrode 1131D are connected to each other inside the insulation substrate 110.

Thus, when a portion of the internal wiring 4D connected to the second connection electrode 1132D is exposed on the bottom surface 7 of the recessed portion 111, while the internal wiring 4D connected to the first connection electrode 1131D is not exposed on the bottom surface 7 of the recessed portion 111, then the first connection electrode 1131D and the second connection electrode 1132D with the exposed internal wiring 4D are not rotationally symmetric with respect to the center of the second surface S2. That is, when the first connection electrode 1131D is rotated by 180 degrees around the center of the second surface S2 as a rotation axis, the first connection electrodes 1131D do not overlap the second connection electrode 1132D nor the exposed internal wiring 4D.

This allows a portion of the internal wiring 4D to be used as an alignment mark, making it easier to determine the orientation of the wiring board 100D.

The first through-hole conductor 1151D may be located inside the first external electrode 1141 and shifted from the center of the first connection electrode 1131D toward the inner walls of the recessed portion 111 in a plane perspective. The second through-hole conductor 1152D may be located inside the third external electrode 1143 and shifted from the center of the second connection electrode 1132D toward the inner walls of the recessed portion 111 in a plane perspective.

### Sixth Embodiment

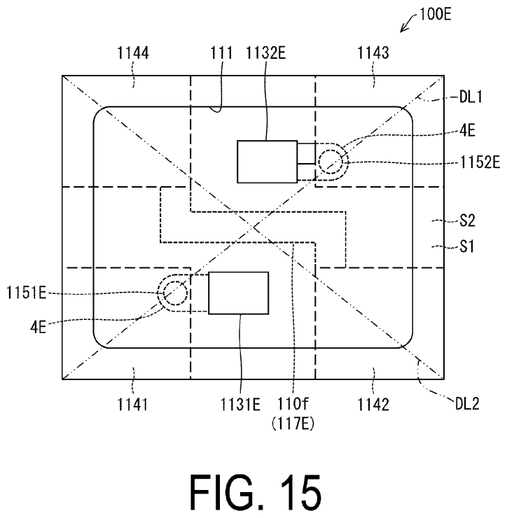

FIG. 15 is a perspective view of the configurations of upper and lower surfaces of a wiring board 100E according to a sixth embodiment when superimposed.

The wiring board 100E includes a first connection electrode 1131E, a second connection electrode 1132E, a first through-hole conductor 1151E, a second through-hole conductor 1152E, and an internal wiring 4E.

The first connection electrode 1131E and the second connection electrode 1132E may be located at positions of point symmetry with respect to the center of the second surface S2.

The first connection electrode 1131E may be located at a position not at all overlapping the first external electrode 1141 in a plane perspective. The first connection electrode 1131E is connected to the first external electrode 1141 via the internal wiring 4E and the first through-hole conductor 1151E extending from the first surface S1 toward the bottom surface 7.

The second connection electrode 1132E may be located at a position not at all overlapping the third external electrode 1143 in a plane perspective. The second connection electrode 1132E is connected to the third external electrode 1143 via the internal wiring 4E and the second through-hole conductor 1152E extending from the first surface S1 toward the bottom surface 7.

The connection wiring 117E may have a first portion extending along a direction toward the third external electrode 1143 from the second external electrode 1142 in a plan view. The connection wiring 117E may have a second portion extending along a direction toward the fourth external electrode 1144 from the third external electrode 1143 and a third portion extending along a direction toward the fourth external electrode 1144 from the first external electrode 1141. Thus, the connection wiring 117E may be formed in a crank shape.

Even when the first connection electrode 1131E is moved to a position closer to the second external electrode 1142 than the first connection electrode 1131D illustrated in FIG. 14, and the second connection electrode 1132E is moved to a position closer to the fourth external electrode 1144 than the second connection electrode 1132D illustrated in FIG. 14, the connection wiring 117E configured as described above can decrease the likelihood of short-circuiting between the connection wiring 117E and the first connection electrode 1131E and between the connection wiring 117E and the second connection electrode 1132E, whereby the degree of freedom in the wiring design of the wiring board 100E can be improved.

The connection wiring 117E may have a first portion extending from the second external electrode 1142 to the fourth external electrode 1144 in a plan view and also extending in a curved manner away from the first connection electrode 1131E. The connection wiring 117E may have a second portion extending in a curved manner away from the second connection electrode 1132E. Thus, the connection wiring 117E may be formed in a curved S-shape.

As described above, the connection wiring 117E is configured to be bent or curved between the second external electrode 1142 and the fourth external electrode 1144. Accordingly, even when the first connection electrode 1131E is shifted from the corner portion of the bottom surface 7 of the recessed portion 111 toward the center side, or when the shape of the first connection electrode 1131E is changed to extend toward the center side, or when the inner end portion of the first connection electrode 1131E is located even closer to the center side, the distance between the first connection electrode 1131E and the connection wiring 117E can be made longer than the linear connection wiring 117. This ensures insulation between the connection wiring 117E and the first connection electrode 1131E.

### Seventh Embodiment

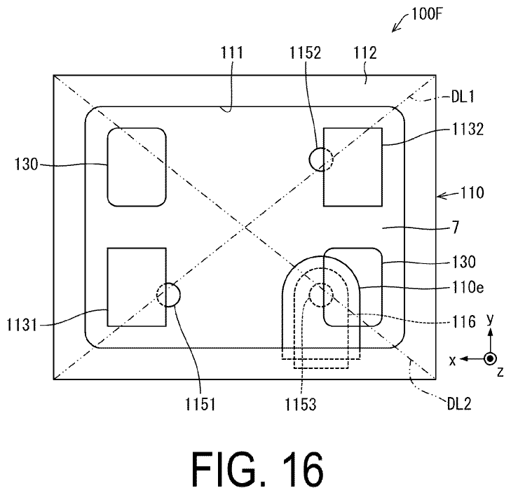

FIG. 16 is a plan view of a wiring board 100F according to a seventh embodiment.

The wiring board 100F further includes a pillow portion 130. A total of two pillow portions 130 are provided, one each at the corner portion of the recessed portion 111 along one of the diagonal lines of the bottom surface 7 of the recessed portion 111 in a plan view. The pillow portion 130 is an insulator having a rectangular shape in a plan view and protrudes from the bottom surface 7 of the recessed portion 111. The outer edge of the pillow portion 130 may be adjacent to the frame portion 110a.

The height of the pillow portion 130 may be substantially the same as the upper surface of the first connection electrode 1131. Alternatively, the height of the pillow portion 130 may be substantially the same as the height of the thickness of the first connection electrode 1131 added with the thickness of the bonding material 160.

The pillow portion 130 may be made of an insulating inorganic material. The insulating inorganic material is a ceramic such as an aluminum oxide sintered body (an alumina ceramic), an aluminum nitride sintered body, a mullite sintered body, a glass-ceramic sintered body, or the like.

The pillow portion 130 is located separated from the wall surface of the recessed portion 111. In other words, the pillow portion 130 may be a floating island. When the first and second connection electrodes 1131 and 1132 and the two pillow portions 130 are each positioned on the floating island portion 2, the floating island is located at each of the four corner portions, making the plan view shape of the four floating islands of the wiring board 100F be symmetrical, thus achieving excellent flatness.

The pillow portion 130 allows a piezoelectric oscillating element to be mounted horizontally and stably. The pillow portion 130 can decrease the likelihood of breakage of the piezoelectric oscillating element when the electronic device 10 is subject to a shock.

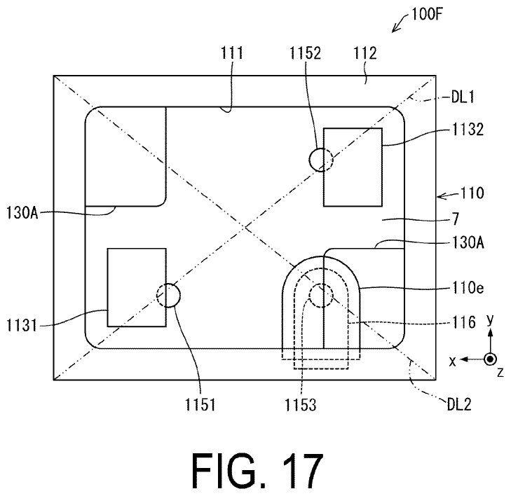

FIG. 17 is a plan view of a variation of the wiring board 100F.

The wiring board 100F may include a pillow portion 130A. The pillow portion 130A is connected integrally with the frame portion 110a of the insulation substrate 110 (see FIG. 1) and a total of two pillow portions 130A are provided at the corner portions of the recessed portion 111, one each along one of the diagonal lines of the bottom surface 7 of the recessed portion 111. The pillow portions 130A are connected to the frame portion 110a integrally and are therefore stronger than the pillow portions 130.

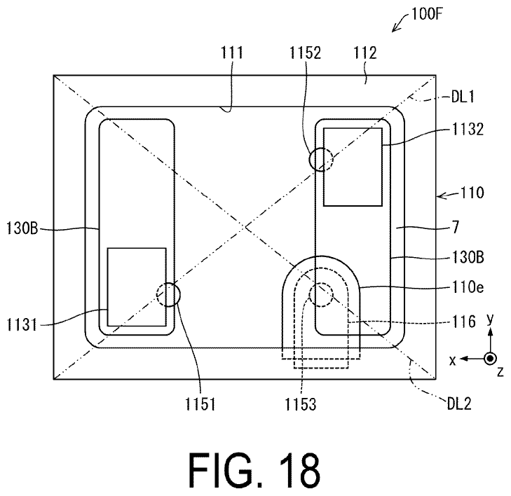

FIG. 18 is a plan view of another variation of the wiring board 100F.

The wiring board 100F may include a pillow portion 130B. The pillow portion 130B is located separated from the wall surface of the recessed portion 111. In other words, the pillow portion 130B may be a floating island. A total of two pillow portions 130B are provided facing each other along the short sides of the bottom surface 7 of the recessed portion 111. The first and second connection electrodes 1131 and 1132 are located on the pillow portions 130B. The upper surfaces of the first and second connection electrodes 1131 and 1132 may be flush with the pillow portions 130B. That is, a portion of each of the two pillow portions 130B may be the floating island portion 2 (see FIG. 6) where the first and second connection electrode 1131 or 1132 is located, and the remaining portion may function as the pillow portions supporting the piezoelectric oscillating element. In other words, in the wiring board 100F, the first and second connection electrodes 1131 and 1132 may be located on the floating island portions 2, while the pillow portions 130B may be integrated with the floating islands and extend in the short-side direction of the bottom surface 7.

Thus, the pillow portions 130B include the integrated floating island portions 2 where the first and second connection electrodes 1131 and 1132 are located and are therefore even stronger than the pillow portions 130A.

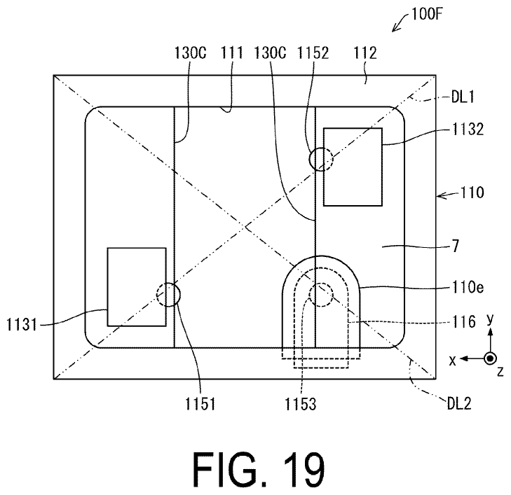

FIG. 19 is a plan view of still another variation of the wiring board 100F.

The wiring board 100F may include a pillow portion 130C. The pillow portion 130C is different from the pillow portion 130B illustrated in FIG. 18 in that the pillow portion 130C is integrally formed with the frame portion 110a. Two pillow portions 130C are provided facing each other along the short sides of the bottom surface 7 of the recessed portion 111. Thus, the pillow portions 130C are formed integrally with the frame portion 110a and are therefore even stronger than the pillow portions 130B.

The invention according to the present disclosure has been described above based on the various drawings and examples. However, the invention according to the present disclosure is not limited to each embodiment described above. That is, the invention according to the present disclosure can be modified in various ways within the scope illustrated in the present disclosure, and embodiments obtained by appropriately combining the technical means disclosed in different embodiments are also included within the technical scope of the invention according to the present disclosure. In other words, those skilled in the art can easily make various variations or modifications based on the present disclosure. Note that these variations or modifications are included within the scope of the present disclosure.

### REFERENCE SIGNS

1 Electronic module
2 Floating island portion
3 Coating portion
4 Internal wiring
5 First internal wiring
6 Second internal wiring
7 Bottom surface
10 Electronic device
100 Wiring board
110 Insulation substrate
111 Recessed portion
113 Connection electrode
114 External electrode
117 Connection wiring
130 Pillow portion
150 Electronic component
200 Module board
1131 First connection electrode
1132 Second connection electrode
1141 First external electrode
1142 Second external electrode
1143 Third external electrode
1144 Fourth external electrode
1151 First through-hole conductor
1152 Second through-hole conductor
S1 First surface
S2 Second surface
DL1 First Diagonal Line
DL2 Second Diagonal Line

1. A wiring board comprising:
an insulation substrate having a first surface, a second surface located on an opposite side of the first surface, and a recessed portion opened on the second surface, the insulation substrate having a rectangular shape in a plan view;
an external electrode located on the first surface; and
a connection electrode located on a bottom surface of the recessed portion,
wherein the external electrode comprises
a first external electrode and a third external electrode located at opposing corner portions along a first diagonal line of the first surface and electrically connected to the connection electrode, and
a second external electrode and a fourth external electrode located at opposing corner portions along a second diagonal line of the first surface,
the second external electrode and the fourth external electrode being connected by a connection wiring located inside the insulation substrate and comprising
the wiring board further comprises
a first through-hole conductor at least partially overlapping the first external electrode in a plane perspective and extending toward the bottom surface from the first surface, and
a second through-hole conductor at least partially overlapping the third external electrode in a plane perspective and extending toward the bottom surface from the first surface, and
the connection electrode comprises
a first connection electrode connected to the first external electrode via the first through-hole conductor, and
a second connection electrode connected to the third external electrode via the second through-hole conductor,
the first connection electrode and the second connection electrode being located at positions along the first diagonal line in a plane perspective.

2. The wiring board according to claim 1,
wherein the first through-hole conductor is located inside the first external electrode and shifted from a center of the first connection electrode in a direction opposite to an inner wall of the recessed portion in a plane perspective.

3. The wiring board according to claim 2,
wherein the first through-hole conductor is at least partially located outside the first connection electrode in a plane perspective.

4. The wiring board according to claim 1,
wherein a floating island portion having a protruding shape is located on the bottom surface of the recessed portion, and
the first connection electrode is located on the floating island portion.

5. The wiring board according to claim 1,
wherein a portion of an end surface on a side of the bottom surface of the first through-hole conductor is connected to the first connection electrode, and
an insulating coating portion is located between the remaining portion of the end surface of the first through-hole conductor and the bottom surface of the recessed portion.

6. The wiring board according to claim 1, further comprising:
an internal wiring being connected to an end surface on a side of the bottom surface of the first through-hole conductor, at least a portion of the internal wiring extending along a plane substantially parallel to the first surface, and the internal wiring being provided with the first through-hole conductor located inside the internal wiring in a plane perspective; and
a coating portion being located between the internal wiring and the bottom surface and adjacent to the first connection electrode in a plane perspective.

7. The wiring board according to claim 1, further comprising:
a first internal wiring being connected to an end surface on a side of the bottom surface of the first through-hole conductor, at least a portion of the first internal wiring extending along a plane substantially parallel to the first surface, and the first internal wiring being provided with the first through-hole conductor located inside the first internal wiring in a plane perspective;
a coating portion being located between the first internal wiring and the bottom surface, the coating portion being provided with the first through-hole conductor located inside the coating portion in a plane perspective; and
a second internal wiring connecting the first internal wiring and the first electrode.

8. The wiring board according to claim 1,
wherein the first connection electrode and the second connection electrode are located at positions of point symmetry with respect to a center of the second surface.

9. The wiring board according to claim 1,
wherein the connection wiring linearly extends from the second external electrode to the fourth external electrode in a plan view.

10. The wiring board according to claim 1,
wherein the connection wiring extends from the second external electrode to the fourth external electrode in a plan view, and comprises a first portion extending in a curved manner away from the first connection electrode in a plan view and a second portion extending in a curved manner away from the second connection electrode in a plan view.

11. The wiring board according to claim 1,
wherein the connection wiring comprises a first portion extending along a direction from the second external electrode toward the third external electrode, a second portion extending along a direction from the third external electrode toward the fourth external electrode, and a third portion extending along a direction from the first external electrode toward the fourth external electrode, in a plan view.
wherein a shape of the first connection electrode and a shape of the second connection electrode are different in a plan view.

13. An electronic device comprising:
the wiring board according to claim 1, and
an electronic component connected to the wiring board.

14. An electronic module comprising:
the electronic device according to claim 13; and
a module board connected to the electronic device.

15. A wiring board comprising:
an insulation substrate having a first surface, a second surface located on an opposite side of the first surface, and a recessed portion opened on the second surface, the insulation substrate having a rectangular shape in a plan view;
an external electrode located on the first surface; and
a connection electrode located on a bottom surface of the recessed portion,
wherein the external electrode comprises
a first external electrode and a third external electrode located at opposing corner portions along a first diagonal line of the first surface and electrically connected to the connection electrode, and
a second external electrode and a fourth external electrode located at opposing corner portions along a second diagonal line of the first surface,
the second external electrode and the fourth external electrode being connected by a connection wiring located inside the insulation substrate and comprising a portion inclined with respect to the first surface,
the wiring board further comprises
a first through-hole conductor at least partially overlapping the first external electrode in a plane perspective and extending toward the bottom surface from the first surface, and
a second through-hole conductor at least partially overlapping the third external electrode in a plane perspective and extending toward the bottom surface from the first surface, and the connection electrode comprises
a first connection electrode connected to the first external electrode via the first through-hole conductor, and
a second connection electrode connected to the third external electrode via the second through-hole conductor,
the first connection electrode and the second connection electrode being located at positions of point symmetry with respect to a center of the second surface.
